(19) United States
(12) Patent Application Publication
(10) Pub. No.: US 2014/0166348 A1
(43) Pub. Date: Jun. 19, 2014

(54) PRINTED CIRCUIT BOARD

(71) Applicant: SAMSUNG ELECTRO-MECHANICS CO., LTD., Suwon (KR)

(72) Inventor: Suk Hyeon Cho, Suwon (KR)

(73) Assignee: SAMSUNG ELECTRO-MECHANICS CO., LTD., Suwon (KR)

(21) Appl. No.: 14/106,135

(22) Filed: Dec. 13, 2013

(30) Foreign Application Priority Data
Dec. 17, 2012 (KR) 10-2012-0147506

(51) Int. Cl. H05K 1/02

(52) U.S. Cl. CPC H05K 1/0271
USPC 174/257; 174/250

(57) ABSTRACT

Disclosed herein is a printed circuit board capable of suppressing warpage due to a difference in thermal expansion coefficients with circuit patterns in the same layer by way of forming a filling material having a thermal expansion coefficient similar to that of the circuit pattern between the circuit patterns and on the surface. Further, on a surface of the filling material, a laminate having a thermal expansion amount lower than that of the filling material so that overall thermal expansion coefficients of the printed circuit board is lowered, and an insulation material having a lower thermal expansion coefficient and thus rarely flowing is easily attached.

### CROSS REFERENCE TO RELATED APPLICATION

This application claims the benefit of Korean Patent Application No. 10-2012-0147506, filed on Dec. 17, 2012, entitled “Printed Circuit Board,” which is hereby incorporated by reference in its entirety into this application.

### BACKGROUND OF THE INVENTION

1. Technical Field

The present invention relates to a printed circuit board.

2. Description of the Related Art

As technologies for responding to high-density of semiconductor chips and high speed signal transmission, in place of existing chip size packaging (CSP) mounting or wire bonding mounting, flip chip mounting in which a semiconductor chip sites directly on a circuit board is increasingly used.

In order to implement flip chip mounting, a highly dense and highly reliable board is required. However, actually the circuit board specification cannot keep up with highly densed semiconductor chips, and thus it is urgent to develop a next generation technology for circuit boards for flip chip mounting. The specification of flip chip mounting board is closely related to high speed, high level semiconductor specification in electronic markets, and there are many challenges, for example, to achieve fine circuits, excellent electronic properties, high reliability, high speed signal transmission, and high functionality.

In the prior art, a method of manufacturing printed circuit board for flip chip mounting includes forming through holes in a thin core material, plugging the through holes with plugging ink and the like, and then performing copper plating and etching to thereby form circuits on the core layer, as disclosed in Patent Document 1, for example.

Then, insulation layers, micro vias, and circuits are repeatedly formed on both sides of the core layer where the circuits are formed, thereby manufacturing a multi-layered board.

Here, the material used for the insulation layers form on both sides of the core layer are identical, and are made by dispersing an inorganic filler with polymer resin as a base or by laminating glass cloth and polymer resin.

The printed circuit board according to the prior art, however, uses a thin core and thus the board has low strength. Therefore, warpage of the board happens due to the difference in thermal expansion coefficients of a chip and the board when the chip is mounted on the board using solder, and thus reliability of the flip chip mounting type packaging may be lowered.

In addition, since the thin core is used and thus the board has low strength, if there is a difference in volume of copper circuits in upper and lower surfaces of the board, warpage of the board happens due to the difference in thermal expansion coefficients of the upper and lower surfaces of the board at the time of solder bump reflow, so that defects occur on the chip.

### PRIOR ART DOCUMENT

### Patent Document

(Patent Document 1) Korean Patent Laid-Open Publication No. 2011-0029469 (published on Mar. 23, 2011)

### SUMMARY OF THE INVENTION

The present invention has been made in an effort to provide a printed circuit board to suppress warpage due to a difference in circuit volumes.

Further, the present invention has been made in an effort to provide a printed circuit board to suppress warpage due to a difference in thermal expansion coefficients of upper and lower sides.

According to a first preferred embodiment of the present invention, there is provided a printed circuit board, including: a first layer including circuit patterns and a filling material filling between the circuit patterns; and a second layer laminated on a surface of the first layer, wherein the second layer is made of an insulation material having a thermal expansion coefficient lower than that of the filling material.

The filling material may have a thermal expansion coefficient ranging from that lower by 10% to that higher by 10% than the thermal expiation coefficient of a conductive metal material forming the circuit patterns.

The filling material may cover the circuit patterns.

The filling material may be made of an insulation material having a thermal expansion coefficient from 10 to 20 ppm/° C. at a temperature from 25° C. to 260° C.

The filling material may contain a filler, in which the filler may be made of a silica-based material and may be contained in the filling material with the size and content adjusted.

According to a second preferred embodiment of the present invention, there is provided a printed circuit board, including: a core layer; an upper laminate disposed on the core layer; and a lower laminate disposed under the core layer, wherein a sum of average thermal expansion coefficients of the upper laminate is equal to a sum of average thermal expansion coefficients of the lower laminate.

Each of the upper laminate and the lower laminate may include multiple layers, and the average thermal expansion coefficient of each of the multiple layers may be associated with thermal expansion coefficients of elements forming each of the layers, elastic moduli of the elements for each of the layers, and volume ratios of the elements for each of the layers.

Each of the upper laminate and the lower laminate may include at least one insulation layer containing a filler for correcting the thermal expansion coefficient.

The filler may be made of a silica-based material, in which the filler may be dispersed and contained in the insulation layer with the type, size and content adjusted.

The core layer may be a rigid insulation layer or may be a copper clad laminate (CCL) with copper foils on both sides of an insulation layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a printed circuit board according to a first preferred embodiment of the present invention;

FIG. 2 is a cross-sectional view of a printed circuit board according to a second preferred embodiment of the present invention;

FIG. 3 is a cross-sectional view of a printed circuit board according to a third preferred embodiment of the present invention; and

FIG. 4 is a cross-sectional view of a printed circuit board according to a fourth preferred embodiment of the present invention.

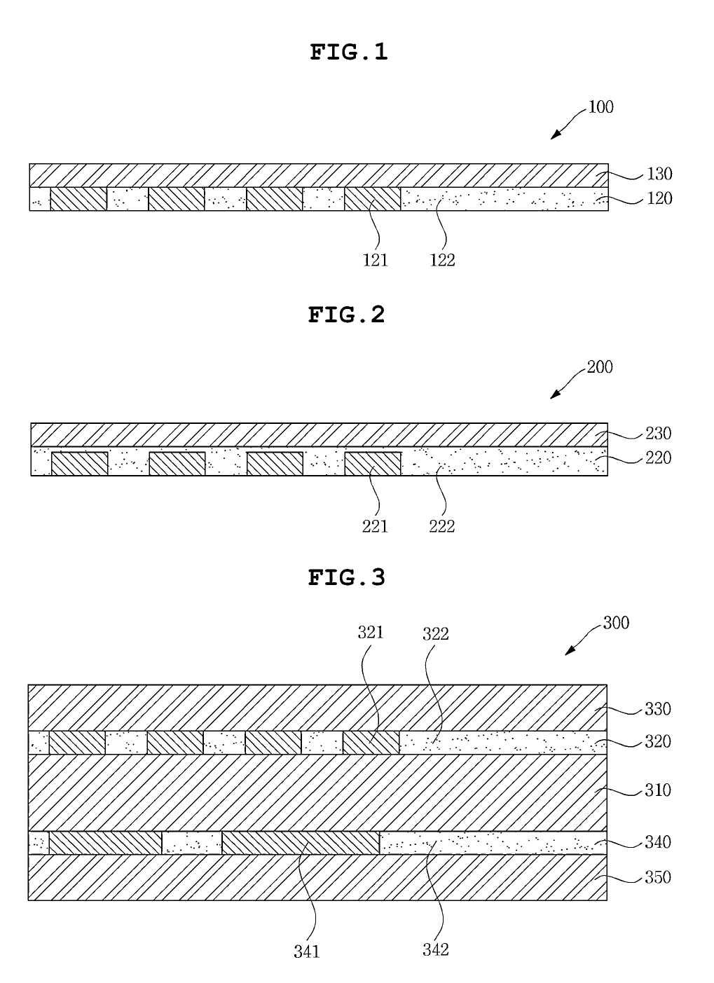

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

A printed circuit board 100 according to the first preferred embodiment of the present invention is a coreless printed circuit board having no core layer and may include a lower layer 120 consisting of circuit patterns 121 and filling materials 122 between the circuit patterns 121, and an upper layer 130 disposed on the lower layer 120 and formed of an insulation material having a thermal expansion coefficient different from that of the filling materials 122.

The filling materials 122 may be formed of an insulation material having a thermal expansion coefficient similar to that of a conductive metal material forming the circuit patterns 121, so that warpage due to the difference in thermal expansion coefficients may be prevented. To this end, the filling materials 122 may contain a filler so that it has a thermal expansion coefficient ranging from that lower by 10% to that higher by 10% than the thermal expansion coefficient of the conductive metal material forming the circuit patterns 121.

Specifically, the filling material 122 is formed of an insulation material having a thermal expansion coefficient from 10 to 20 ppm/° C. at between 25° C. and 260° C. For example, the filler may be formed of silica based material such as SiO₂. The thermal expansion coefficient of the filling material 122 may be set by adjusting the size and the content of the filler.

The upper layer 130 may be formed of an insulation material having a thermal expansion coefficient different from that of the filling material 122, e.g., a thermal expansion coefficient lower than that of the filling material 122 by 10%.

The printed circuit board 100 according to the first preferred embodiment of the present invention includes the lower layer 120 including the filling material 122 containing a filler to reduce the difference in thermal expansion coefficients with the circuit patterns 121 and the upper layer 130 having a thermal expansion efficient lower than that of the filling material 122 by 10%, so that warpage due to the difference in the thermal expansion coefficients between the lower layer 120 and the upper layer 130 can be prevented.

Optionally, a printed circuit board 200 according to the second preferred embodiment of the present invention illustrated in FIG. 2 may include a lower layer 220 in which a filling material 222 covers the surfaces of circuit patterns 221 and an upper layer 230 disposed on the filling material 222 covering the surfaces of the circuit patterns 221 and having a thermal expansion coefficient lower than that of the filling material 222 by 10%.

Hereinafter, a printed circuit board 300 according to the third preferred embodiment of the present invention will be described with reference to FIG. 3. FIG. 3 is a cross-sectional view of a printed circuit board according to the third preferred embodiment of the present invention.

The printed circuit board 300 according to the third preferred embodiment of the present invention may include a core layer 310, an upper laminate disposed on the core layer 310, and a lower laminate disposed under the core layer 310.

For example, as shown in FIG. 3, the upper laminate may include a first upper layer 320 that is disposed on the core layer 310 and includes upper circuit patterns 321 and an upper filling material 322 surrounding the upper circuit patterns 321, and a second upper layer 330 that is disposed on the first upper layer 320 and has a thermal expansion coefficient lower than that of the upper filling material 322 by, for example, 10%.

For example, the lower laminate may include a first lower layer 340 that is disposed under the core layer 310 and includes lower circuit patterns 341 and a lower filling material 342 surrounding the lower circuit patterns 341, and a second lower layer 350 that is disposed under the first lower layer 340 and has a thermal expansion coefficient lower than that of the lower filling material 342 by, for example, 10%.

It is apparent that the numbers of the upper laminates and the lower laminates are not limited thereto but may include a structure having three-layer or higher circuit patterns.

The core layer 310 may be a rigid insulation layer or a copper-clad laminate (CCL) which has copper foils on both sides of an insulation layer.

Specifically, the CCL is a raw material for manufacturing a PCB and is formed by laminating copper foils on surfaces of an insulation layer. Types of CCL may include a glass/epoxy CCL, a heat-resistant resin CCL, a paper/phenol CCL, a high-frequency CCL, a flexible CCL (a polyimide film), and a composite CCL and the like, and the glass/epoxy CCL is commonly used in manufacturing a double-sided PCB and a multi-layered PCB.

The glass/epoxy CCL is configured of a reinforced material formed by permeating an epoxy resin into a glass fiber or an organic fiber and copper foils. The glass/epoxy CCL may be classified according to the type of reinforced material. In general, there are grades defined by the National Electrical Manufactures Association (NEMA) regarding the reinforced material and thermal resistance, such as FR-1 to FR-5. Among the grades, FR-4 is most commonly used, and recently FR-5 is increasingly used which has improved glass transition temperature property of resin T_{g}.

The first upper layer 320 includes upper a plurality of circuit patterns 321, and the first lower layer 340 includes a plurality of lower circuit patterns 341. In general, the volume occupied by the upper circuit patterns 321 in the first upper layer 320 and the volume occupied by the lower circuit patterns 341 in the first lower layer 340 are different from each other.

For example, in FIG. 3, the volume occupied by the upper circuit patterns 321 may be smaller than the volume occupied by the lower circuit patterns 341.

Accordingly, the upper laminate including the upper circuit patterns 321 and the lower laminate including the lower circuit patterns 341 have different thermal expansion coefficients, so that warpage may occur due to the different thermal expansion coefficients.

Accordingly, the printed circuit board 300 according to the third preferred embodiment of the present invention has a symmetric structure so that the sums of average thermal expansion coefficients of the upper laminate and the lower laminate with respect to the core layer 310 are equal to each other, as expressed by Equation 1.

ΣCTE_{H}=Σ=HCTE_{L} [Equation 1]

Where CTE_{H} denotes an average thermal expansion coefficient of each of the layers forming the upper laminate, and CTE_{L} denotes an average thermal expansion coefficient of each of the layers forming the lower laminate.

Specifically, as expressed by Equation 2, correction may be made such that the sum of the average thermal expansion coefficient CTE₁₂₀ of the first upper insulation layer 120 including the upper circuit patterns 121 and the average thermal expansion coefficient CTE₁₃₀ of the second upper insulation layer 130 is equal to the sum of the average thermal expansion coefficient CTE₁₄₀ of the first lower insulation layer 140 including the lower circuit patterns 141 and the average thermal expansion coefficient CTE₁₅₀ so of the second lower insulation layer 150.

CTE₃₂₀+CTE₃₃₀=CTE₃₄₀+CTE₃₅₀ [Equation 2]

Here, the average thermal expansion coefficients CTE_{L} of the layers may be expressed by Equation 3 depending on elements forming the layers, for example, two elements.

$${CTE}_{1} = \frac{{α}_{1} {E}_{1} {V}_{1} + {α}_{2} {E}_{2} {V}_{2}}{{E}_{1} {V}_{1} + {E}_{2} {V}_{2}} \qquad [ Equation 3 ]$$

Where α₁ denotes the thermal expansion coefficient (ppm/° C.) of a first element forming a layer, E₁ denotes an elastic modulus GPa of the first element, V₁ denotes a volume ratio of the first element, α₂ denotes the thermal expansion coefficient (ppm/° C.) of a second element forming a layer, E₂ denotes an elastic modulus GPa of the second element, V₂ denotes a volume ratio of the second element, and V₁ and V₂ meet V₁+V₂=1.

For example, in the case of calculating the average thermal expansion coefficient CTE₁₂₀ for the first upper layer 320, α₁ corresponds to the thermal expansion coefficient of copper forming the upper circuit patterns 121, E₁ corresponds to the elastic modulus of the copper material forming the upper circuit patterns 121, V₁ corresponds to the volume ratio of the upper circuit pattern 321 to the first upper layer 320, α₂ corresponds to the thermal expansion coefficient of the upper filling material 322 forming the first upper layer 320, E₂ corresponds to the elastic modulus of the upper filling material 322, and V₂ corresponds to the volume ratio of the upper filling material 322 to the first upper layer 320. Here, V₁ and V₂ are calculated with respect to the first upper layer 320 and thus V₁+V₂=1.

As such, the thermal expansion coefficients of the filling materials 322 and 342 or insulation materials forming the layers may be set so that the sums of the average thermal expansion coefficients of the upper laminate and the lower laminate are symmetric with respect to the core layer 310 as expressed by Equation 1.

Specifically, the upper filling material 322 of the first upper layer 320 and the lower filling material 342 of the first lower layer 340 may contain a filler for correcting thermal expansion coefficients.

Here, the filler may be one made of silica based material such as SiO₂.

It is apparent that the second upper layer 330 or the second lower layer 350 may also contain a filler for correcting thermal expansion coefficients.

Accordingly, the printed circuit board 300 according to the third preferred embodiment of the present invention has a symmetric structure with respect to the core layer 310 in which the sums of the average thermal expansion coefficients of the upper laminate and the lower laminate are equal, so that warpage occurring due to the difference in thermal expansion coefficients between the upper and lower laminates with respect to the core layer 310 during heat treatment or cooling process can be suppressed.

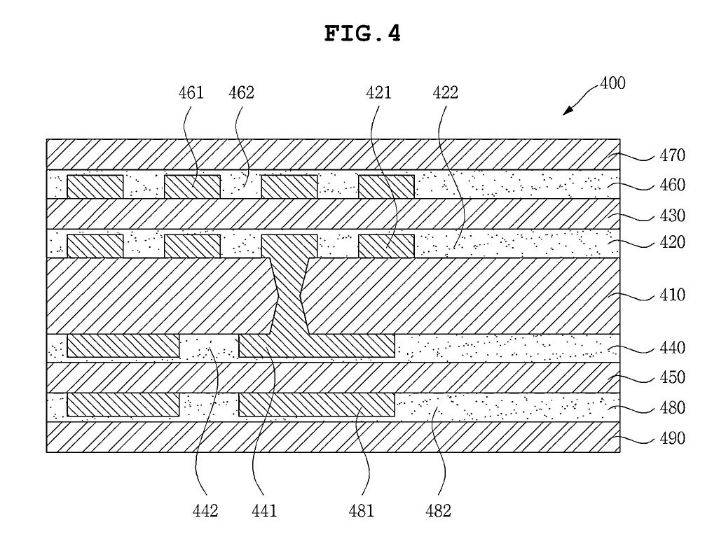

Optionally, a printed circuit board 400 according to the fourth preferred embodiment of the present invention, as shown in FIG. 4, may include an upper laminate and a lower laminate of a multi-layer structure in which filling materials 422, 442, 462 and 482 cover the surfaces of circuit patterns 421, 441, 461 and 481, and layers 430, 450, 470 and 490 have thermal expansion coefficients lower than those of the filling materials 422, 442, 462 and 482 by 10%, for example.

Accordingly, the printed circuit board according to the preferred embodiments of the present invention may prevent warpage and thus improve flatness, so that mounting errors of various components such as chips are reduced, thereby improving reliability of the printed circuit board.

As set forth above, according to the preferred embodiments of the present invention, warpage may be suppressed due to a difference in thermal expansion coefficients of upper and lower sides which is caused by a difference in circuit volumes during heat treatment of the board.

Further, warpage may be suppressed due to a difference in thermal expansion coefficients of upper and lower.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a first layer including circuit patterns and a filling material filling between the circuit patterns; and
a second layer laminated on a surface of the first layer, wherein the second layer is made of an insulation material having a thermal expansion coefficient lower than that of the filling material.

2. The printed circuit board as set forth in claim 1, wherein the filling material has a thermal expansion coefficient ranging from that lower by 10% to that higher by 10% than a thermal expansion coefficient of a conductive metal material forming the circuit patterns.

3. The printed circuit board as set forth in claim 1, wherein the filling material covers the circuit patterns.

4. The printed circuit board as set forth in claim 1, wherein the filling material is made of an insulation material having a thermal expansion coefficient from 10 to 20 ppm/° C. at a temperature from 25° C. to 260° C.

5. The printed circuit board as set forth in claim 1, wherein the filling material contains a filler, wherein the filler is made of a silica-based material and is contained in the filling material with the size and content adjusted.

6. A printed circuit board, comprising:
a core layer;
an upper laminate disposed on the core layer; and
a lower laminate disposed under the core layer,
wherein a sum of average thermal expansion coefficients of the upper laminate is equal to a sum of average thermal expansion coefficients of the lower laminate.

7. The printed circuit board as set forth in claim 6, wherein each of the upper laminate and the lower laminate includes multiple layers, and wherein the average thermal expansion coefficient of each of the multiple layers is associated with thermal expansion coefficients of elements forming each of the layers, elastic moduli of the elements for each of the layers, and volume ratios of the elements for each of the layers.

8. The printed circuit board as set forth in claim 6, wherein each of the upper laminate and the lower laminate includes at least one insulation layer containing a filler for correcting the thermal expansion coefficient.

9. The printed circuit board as set forth in claim 8, wherein the filler is made of a silica-based material, wherein the filler is dispersed and contained in the insulation layer with the type, size and content adjusted.

10. The printed circuit board as set forth in claim 6, wherein the core layer is a rigid insulation layer or is a copper clad laminate (CCL) with copper foils on both sides of an insulation layer.
